(19) United States
(12) Patent Application Publication
(10) Pub. No.: US 2006/0226557 A1
(43) Pub. Date: Oct. 12, 2006

(54) Semiconductor substrate with occurrence of slip suppressed and method of manufacturing the same

(76) Inventor: Akihito Yamamoto, Naka-gun (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/154,645

(22) Filed: Jun. 17, 2005

(30) Foreign Application Priority Data
Apr. 6, 2005 (JP) 2005-109975

(51) Int. Cl. H01L 23/29; H01L 21/00

(52) U.S. Cl. 257/794; 438/799

(57) ABSTRACT

A semiconductor substrate includes a denuded zone that is formed on a surface where a semiconductor device is to be formed, and an oxygen precipitate layer that is formed on at least a part of a surface, which is opposite to the surface where the semiconductor device is to be formed.

### CROSS-REFERENCE TO RELATED APPLICATIONS

This application is based upon and claims the benefit of priority from prior Japanese Patent Application No. 2005-109975, filed Apr. 6, 2005, the entire contents of which are incorporated herein by reference.

### BACKGROUND OF THE INVENTION

1. Field of the Invention

The present invention relates generally to a large-diameter semiconductor substrate with a denuded zone, and more particularly to a semiconductor substrate with occurrence of slip suppressed and a method of manufacturing the same.

2. Description of the Related Art

In recent years, semiconductor substrate have been manufactured using a large-diameter silicon wafer having a diameter of, e.g. about 300 mm. When a back surface of such a large-diameter semiconductor substrate is held by means of a jig, a great stress acts on the substrate due to its own weight. In particular, in the case of a substrate with a low surface oxygen concentration, in which a denuded zone is formed, tends to easily cause slip at a location held by the jig. It is thus difficult to prevent occurrence of slip in a subsequent high-temperature heat treatment step at about 900° C. or above.

As a technique relating to a method of manufacturing a semiconductor substrate, there has already been proposed a method in which an amorphous silicon layer is formed on that surface of a substrate, which is located opposite to a surface provided with an active device region, thereby to enhance the defect-free properties in the active device region (see, e.g. Jpn. Pat. Appln. KOKAI Publication No. 6-342800). The technique of KOKAI 6-342800, however, aims at removing metal contamination or the like from the outside, which occurs during an LSI fabrication process, and does not aim at suppressing occurrence of slip due to the own weight of a substrate. There has been a demand for the advent of a semiconductor substrate capable of suppressing occurrence of slip due to its own weight and a method of manufacturing the same.

### BRIEF SUMMARY OF THE INVENTION

According to a first aspect of the invention, there is provided a semiconductor substrate comprising: a denuded zone that is formed on a surface where a semiconductor device is to be formed; and an oxygen precipitate layer that is formed on at least a part of a surface, which is opposite to the surface where the semiconductor device is to be formed.

According to a second aspect of the invention, there is provided a semiconductor substrate comprising: a denuded zone that is formed on a surface where a semiconductor device is to be formed; a first oxygen precipitate layer that is formed within the semiconductor substrate; and a second oxygen precipitate layer that is formed continuous with the first oxygen precipitate layer and is exposed on a surface, which is opposite to the surface where the semiconductor device is to be formed.

According to a third aspect of the invention, there is provided a method of manufacturing a semiconductor substrate, comprising: forming a film with a low oxygen permeability on a surface of the semiconductor substrate, which is opposite to a surface where a semiconductor device is to be formed; subjecting the semiconductor substrate to heat treatment; and forming an oxygen precipitate layer within the semiconductor substrate, the oxygen precipitate layer being in contact with the film with the low oxygen permeability.

According to a fourth aspect of the invention, there is provided a method of manufacturing a semiconductor substrate, comprising: forming a damage layer on a part of a surface of the semiconductor substrate, which is opposite to a surface where a semiconductor device is to be formed; subjecting the semiconductor substrate to heat treatment; and forming an oxygen precipitate layer in association with the damage layer.

According to a fifth aspect of the invention, there is provided a method of manufacturing a semiconductor device, comprising: holding a semiconductor substrate, which includes an oxygen precipitate layer on a part of a back surface thereof, by means of a jig in such a manner that the jig contacts the oxygen precipitate layer; and performing a process on the semiconductor substrate.

### BRIEF DESCRIPTION OF THE SEVERAL VIEWS OF THE DRAWING

FIG. 1 is a cross-sectional view of a semiconductor substrate according to a first embodiment of the present invention;

FIG. 2A through FIG. 2E illustrate fabrication steps of the semiconductor substrate according to the first embodiment;

FIG. 3A through FIG. 3F illustrate fabrication steps of a semiconductor substrate according to a second embodiment of the invention;

FIG. 4A and FIG. 4B illustrate parts of fabrication steps of a semiconductor substrate according to a third embodiment of the invention;

FIG. 5 shows locations of damage layers formed on the back surface of the semiconductor substrate according to the third embodiment;

FIG. 6 shows a typical example of an oxygen concentration distribution in a depth direction of a denuded zone; and

FIG. 7 shows a typical example of an oxygen concentration distribution in a depth direction of an oxygen precipitate layer.

### DETAILED DESCRIPTION OF THE INVENTION

Embodiments of the present invention will now be described with reference to the accompanying drawings.

### First Embodiment

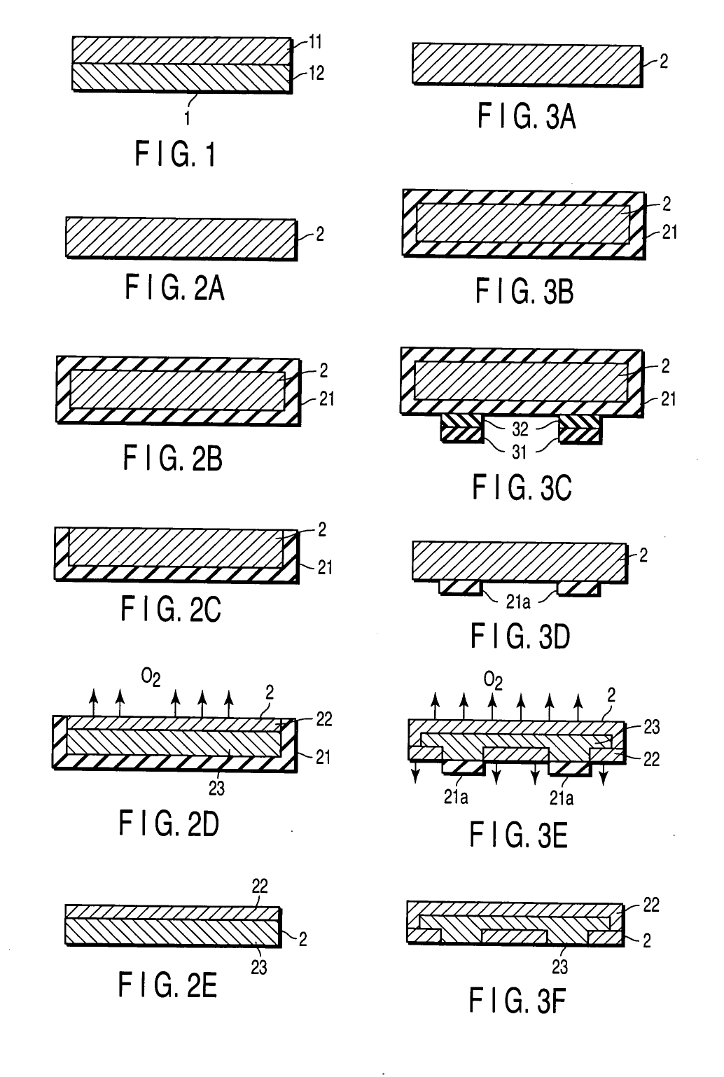

FIG. 1 is a cross-sectional view that shows a semiconductor substrate 1 according to a first embodiment of the invention. The semiconductor substrate 1 includes a denuded zone 11 on its top surface side, which is formed by high-temperature heat treatment, and also includes an oxygen precipitate-containing layer 12 on its back surface side. The top surface, in this context, refers to a surface of the semiconductor substrate 1, where a semiconductor device is to be fabricated. Precipitated oxygen functions to fix dislocation. Thus, even if dislocation occurs, the precipitated oxygen prevents the dislocation from easily moving, and suppresses occurrence of slip.

FIG. 2A to FIG. 2E illustrate fabrication steps of the semiconductor substrate shown in FIG. 1. FIG. 2A shows a silicon semiconductor substrate 2 that is formed by the CZ (Czochralski) method. The substrate 2 has a large diameter of, e.g. 300 mm.

Subsequently, as shown in FIG. 2B, a film 21 with a low oxygen permeability, for instance, a silicon nitride film (Si₃N₄) 21, is formed so as to cover the entire surfaces of the semiconductor substrate 2. Specifically, a silicon nitride film is formed by LP-CVD (Low Pressure Chemical Vapor Deposition) using, e.g. silane (SiH₄) and ammonia (NH₃), or dichlorsilane (SiH₂Cl₂) and ammonia (NH₃). The conditions for the film formation are a temperature of, e.g. 700° C. or above, and a pressure of several Torr, preferably 1 Torr or less. In this manner, the silicon nitride film 21 is formed on the entire surfaces of the substrate 2. The thickness of the silicon nitride film 21 should preferably be several-hundred Å or more, for instance, about 20 to 30 nm.

Following the above step, as shown in FIG. 2C, phosphoric acid, for instance, is sprayed on the top surface of the substrate 2, thereby etching away that part of the silicon nitride film 21, which covers the top surface of the substrate 2.

The semiconductor substrate 2 is then subjected to heat treatment at, e.g. 1,000° C. or above in a non-oxidizing atmosphere. The pressure is, e.g. 1 atm. Thereby, as shown in FIG. 2D, oxygen that is contained in the semiconductor substrate 2 is outdiffused from the top surface of the substrate 2. As a result, a denuded zone 22 with a low oxygen concentration is formed in a surface portion of the semiconductor substrate 2.

On the other hand, oxygen is hardly outdiffused from the back surface and side surfaces of the semiconductor substrate 2 since they are covered with the silicon nitride film 21 that has low oxygen permeability. Thus, an oxygen precipitate layer 23 is formed on the bottom side of the substrate 2.

The non-oxidizing atmosphere should preferably be a gas that forms no reaction product on the Si surface, such as H₂ or an inert gas of Ar, He, Xe, etc. The condition for the high-temperature heat treatment should be a temperature of 1000° C. or above, in order to form a satisfactory denuded zone. For example, when heat treatment is conducted at 1 atmospheric pressure and 1200° C. for one hour, a denuded zone of about 10 μm or more can be formed (in FIG. 2D, the depth of the denuded zone is not based on actual measurement).

Finally, the silicon nitride film 21 is removed, as shown in FIG. 2E. The silicon nitride film 21 is removed, for example, by spraying phosphoric acid on the silicon nitride film 21 and etching the same. The removal of the silicon nitride film 21 is not indispensable. The silicon nitride film 21 need not be removed if no warp occurs in the substrate 2 due to a difference in expansion coefficient between the substrate 2 and silicon nitride film 21 in a subsequent heat treatment. For example, when the thickness of the silicon nitride film 21 is about 20 nm to 30 nm and small, only a low stress acts on the substrate 2 due to a difference in expansion coefficient between the silicon nitride film 21 and the substrate 2. It is thus possible to leave the silicon nitride film 21.

According to the above-described first embodiment, the oxygen precipitate layer 23 with a high oxygen concentration is formed on the back side of the substrate 2. Since the precipitated oxygen functions to fix a dislocation, such a dislocation, if occurs, does not easily move and occurrence of slip can be suppressed.

### Second Embodiment

FIG. 3A to FIG. 3F illustrate fabrication steps of a semiconductor substrate according to a second embodiment of the invention. Fabrication steps up to the formation of a silicon nitride film 21, as shown in FIG. 3A and FIG. 3B, which covers the entire surfaces of the silicon semiconductor substrate 2 formed by the CZ method, are common to the first embodiment.

Subsequently, in this embodiment, an oxide film is formed on the silicon nitride film 21 on the back side of the substrate 2, and a resist is coated on the oxide film. The resist is then partly removed, except regions where a jig that holds the substrate in a subsequent step is put in contact. A resist 31, which is left as shown in FIG. 3C, is used as a mask, and the oxide film is removed. Then, the masked oxide film 32 is left.

Using the left resist 31 and oxide film 32 as a mask, the silicon nitride film 21 is partly removed. Thus, as shown in FIG. 3D, a silicon nitride film 21a is left. The silicon nitride film 21 is removed, for example, by spraying phosphoric acid on the silicon nitride film 21 and etching the same.

Then, like the first embodiment, the semiconductor substrate 2 is subjected to heat treatment in a non-oxidizing atmosphere. Thereby, as shown in FIG. 3E, oxygen that is contained in the semiconductor substrate 2 is outdiffused from surface portions of the substrate 2, which are not covered with the silicon nitride film 21a with low oxygen permeability. As a result, a denuded zone 22 is formed in surface portions of the semiconductor substrate 2, except for the region where outdiffusion of oxygen hardly occurs by the presence of the silicon nitride film 21a.

FIG. 6 shows a typical example of an oxygen concentration distribution in the depth direction of the thus formed denuded zone 22. It is understood that a layer with a low oxygen concentration, that is, a denuded zone, is formed down to a depth of about 15 μm from the surface.

On the other hand, outdiffusion of oxygen hardly occurs in the parts covered with the silicon nitride film 21a, even after the heat treatment. As a result, an oxygen precipitate layer 23 with a high oxygen concentration, which centers at the part covered with the silicon nitride film 21a, is left.

FIG. 7 shows a typical example of an oxygen concentration distribution in the depth direction of the oxygen precipitate layer 23. As is understood from FIG. 7, the oxygen concentration remains high from the depth of 0 μm in the oxygen precipitate layer.

Finally, the silicon nitride film 21a is removed, as shown in FIG. 3F. The silicon nitride film 21a is removed, for example, by spraying phosphoric acid on the silicon nitride film 21a and etching the same. In the present embodiment, the entire area of the silicon nitride film 21a is smaller than the entire area of the semiconductor substrate. Thus, even if the silicon nitride film 21a is left on the substrate 2, only a low stress acts on the substrate 2 due to a difference in expansion coefficient between the silicon nitride film 21a and the substrate 2. It is thus possible to leave the silicon nitride film 21a.

In a subsequent semiconductor fabrication step, heat treatment is performed at 600° C. or above. In this step, parts of the back surface of the substrate are held by the jig. In general, slip tends to easily occur in the substrate from a contact point between the jig and the semiconductor substrate 2. The jig, which is a support member for supporting the semiconductor substrate 2, supports, for example, a peripheral part of the substrate 2, and contacts at least a part of the substrate 2 to hold the substrate 2. In the present embodiment, however, the oxygen precipitate layer 23 is formed in advance in at least a part of the substrate 2, which corresponds in position to the region where the substrate 2 is held. Thereby, a dislocation, which occurs from the contact part with the jig, can be fixed, and occurrence of slip can be prevented.

An adequate plane-directional dimension of the oxygen precipitate layer that is formed on the back surface is about 0.1 mm or more in diameter, if consideration is given only to the thickness of a distal end portion of the jig. In the actual semiconductor fabrication step, however, a positional displacement may occur when the substrate is held by the jig. Taking this into account, an area of several mm in diameter is considered to be proper.

### Third Embodiment

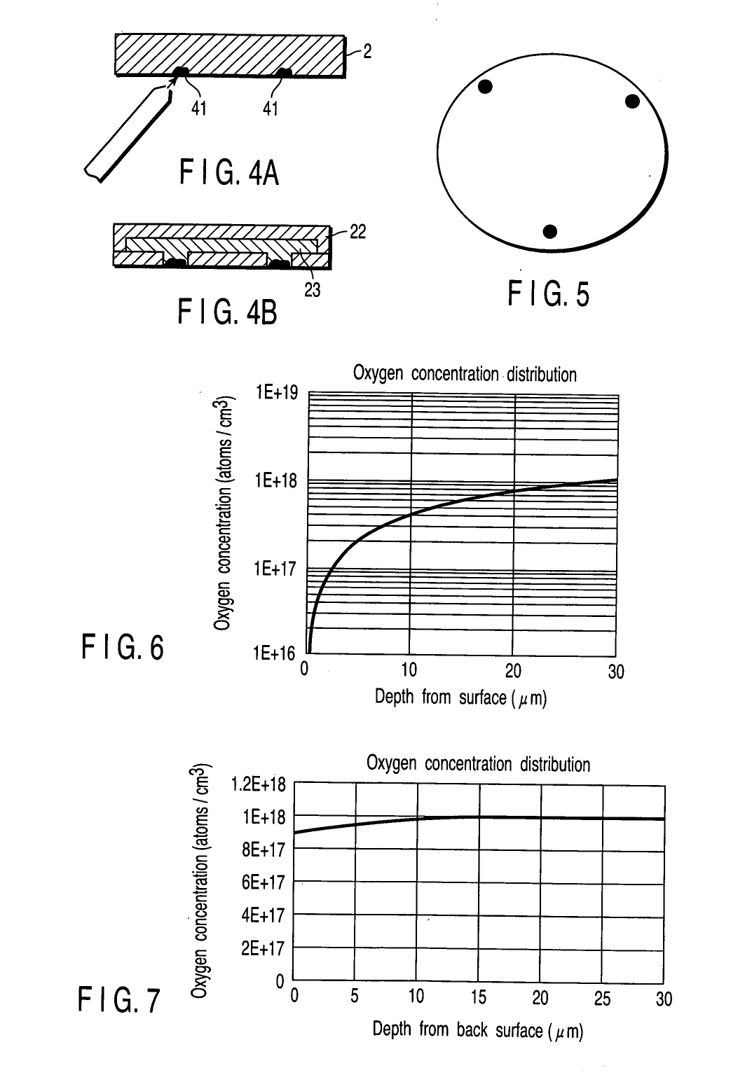

FIG. 4A and FIG. 4B illustrate parts of fabrication steps of a semiconductor substrate according to a third embodiment of the invention.

In this embodiment, as shown in FIG. 4A, a damage layer 41 with minute irregularities is locally formed on the back surface of the substrate 2 by means of, e.g. sandblast. In the sandblast method, particles of SiO₂, etc. are sprayed to create damage on the semiconductor substrate. Other available methods for forming the damage layer 41 include a grinding method that mechanically causes damage, and an ultrasonic method. In actual cases, however, it is easy to form the damage layer 41 by sandblast. Thus, it is preferable to use the sandblast method. The part where the damage layer 41 is formed corresponds in position to the part with which the jig that holds the substrate is put in contact.

FIG. 5 shows locations of damage layers 41 that are formed on the back surface of the semiconductor substrate 2. In this example, three damage layers 41 are formed. The number of damage layers 41 and the locations thereof are not limited, and can freely be chosen in accordance with the parts of the semiconductor substrate 2, which are held by the jig in the semiconductor fabrication step.

Thereafter, the same heat treatment as in the first and second embodiments is performed. As a result, as shown in FIG. 4B, a denuded zone 22 and an oxygen precipitate layer 23 are formed. In the heat treatment step, the parts, where the damage layers 41 are formed, function like the parts that are covered with the silicon nitride films 21a in the second embodiment. In short, the parts where the damage layers 41 are formed suppress outdiffusion of oxygen. Thus, with these parts as starting points, the oxygen precipitate layer 23 is formed within the semiconductor substrate 2.

As mentioned above, the oxygen precipitate has the function of fixing a dislocation, and occurrence of slip is suppressed at the part of the oxygen precipitate. Therefore, the same advantageous effect as in the second embodiment can be obtained. Although it is possible to form a damage layer on the entire back surface of the semiconductor substrate 2 by the sandblast method, irregularities are created on the entire back surface in this case. Consequently, planarity would deteriorate in a subsequent lithography step. In this embodiment, the damage layer 41 is locally formed at controlled positions. Thereby, the adverse effect on the lithography step can be minimized.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor substrate comprising:
a denuded zone that is formed on a surface where a semiconductor device is to be formed; and
an oxygen precipitate layer that is formed on at least a part of a surface, which is opposite to the surface where the semiconductor device is to be formed.

2. The semiconductor substrate according to claim 1, wherein the oxygen precipitate layer includes a part with which a jig that holds the semiconductor substrate is put in contact.

3. The semiconductor substrate according to claim 1, further comprising:
a damage layer that is formed in association with the oxygen precipitate layer.

4. The semiconductor substrate according to claim 3, wherein the damage layer includes a part with which a jig that holds the semiconductor substrate is put in contact.

5. The semiconductor substrate according to claim 1, wherein the oxygen precipitate layer covers the surface, which is opposite to the surface where the semiconductor device is to be formed.

6. A semiconductor substrate comprising:
a denuded zone that is formed on a surface where a semiconductor device is to be formed;
a first oxygen precipitate layer that is formed within the semiconductor substrate; and
a second oxygen precipitate layer that is formed continuous with the first oxygen precipitate layer and is exposed on a surface, which is opposite to the surface where the semiconductor device is to be formed.

7. The semiconductor substrate according to claim 6, wherein the second oxygen precipitate layer includes a part with which a jig that holds the semiconductor substrate is put in contact.

8. The semiconductor substrate according to claim 6, further comprising:
a damage layer that is formed in association with the second oxygen precipitate layer.

9. The semiconductor substrate according to claim 8, wherein the damage layer includes a part with which a jig that holds the semiconductor substrate is put in contact.

10. A method of manufacturing a semiconductor substrate, comprising:
forming a film with a low oxygen permeability on a surface of the semiconductor substrate, which is opposite to a surface where a semiconductor device is to be formed;
subjecting the semiconductor substrate to heat treatment; and
forming an oxygen precipitate layer within the semiconductor substrate, the oxygen precipitate layer being in contact with the film with the low oxygen permeability.

11. The method of manufacturing a semiconductor substrate, according to claim 10, wherein the film with the low oxygen permeability is a silicon nitride film.

12. The method of manufacturing a semiconductor substrate, according to claim 10, wherein the oxygen precipitate layer includes a part with which a jig that holds the semiconductor substrate is put in contact.

13. The method of manufacturing a semiconductor substrate, according to claim 10, wherein the film with the low oxygen permeability is formed on at least a part of said surface that is opposite to the surface where the semiconductor device is to be formed, and
the oxygen precipitate layer is formed on at least said part of the surface that is opposite to the surface where the semiconductor device is to be formed.

14. The method of manufacturing a semiconductor substrate, according to claim 13, wherein the oxygen precipitate layer includes a part with which a jig that holds the semiconductor substrate is put in contact.

15. A method of manufacturing a semiconductor substrate, comprising:
forming a damage layer on a part of a surface of the semiconductor substrate, which is opposite to a surface where a semiconductor device is to be formed;
subjecting the semiconductor substrate to heat treatment; and
forming an oxygen precipitate layer in association with the damage layer.

16. The method of manufacturing a semiconductor substrate, according to claim 15, wherein the damage layer is formed by a sandblast method.

17. The method of manufacturing a semiconductor substrate, according to claim 15, wherein the damage layer is formed by a grinder.

18. The method of manufacturing a semiconductor substrate, according to claim 15, wherein the damage layer is formed by ultrasonic waves.

19. The method of manufacturing a semiconductor substrate, according to claim 15, wherein the oxygen precipitate layer includes a part with which a jig that holds the semiconductor substrate is put in contact.

20. A method of manufacturing a semiconductor device, comprising:
holding a semiconductor substrate, which includes an oxygen precipitate layer on a part of a back surface thereof, by means of a jig in such a manner that the jig contacts the oxygen precipitate layer; and
performing a process on the semiconductor substrate.
